(19) United States
(12) Patent Application Publication
(10) Pub. No.: US 2020/0281092 A1
(43) Pub. Date: Sep. 3, 2020

(54) COOLING DEVICE AND COOLING METHOD

(71) Applicant: TOSHIBA MITSUBISHI-ELECTRIC INDUSTRIAL SYSTEMS CORPORATION, Chuo-ku (JP)

(72) Inventors: Yoshihiro TAWADA, Tokyo (JP); Nobuhiro TAKAHASHI, Tokyo (JP)

(73) Assignee: TOSHIBA MITSUBISHI-ELECTRIC INDUSTRIAL SYSTEMS CORPORATION, Chuo-ku (JP)

(21) Appl. No.: 16/647,708

(22) PCT Filed: Sep. 20, 2017
(86) PCT No.: PCT/JP2017/033972

§ 371 Date: Mar. 16, 2020

(51) Int. Cl. H05K 7/20; H01L 23/467

(52) U.S. Cl. CPC H05K 7/20209; H05K 7/20172; H01L 23/467

(57) ABSTRACT

A cooling device includes a heat pipe connected to the semiconductor chip, a fan for cooling a heat radiating portion of the heat pipe, a temperature sensor for measuring a temperature around the device, and a control unit for controlling the fan. When the temperature measured by the temperature sensor is higher than a reference temperature, the control unit causes the fan to operate at a normal rotation speed, and when the temperature measured by the temperature sensor is not higher than the reference temperature, the control unit stops the rotation of the fan or causes the fan to rotate at a rotation speed equal to or lower than the normal rotation speed.

### TECHNICAL FIELD

Embodiments of the present invention relate to a cooling device and cooling method.

### BACKGROUND

An example of a cooling device is a heat pipe type heat exchanger. Heat pipe type heat exchangers are applied to various fields, and are also used for preventing heat generation of semiconductor elements of power conversion devices.

The power conversion device may be installed outdoors, and for example, in an area such as Hokkaido where the winter temperature is below the freezing point, the power conversion device is operated at a low temperature in the vicinity of the freezing point. Therefore, a refrigerant in the heat pipe may be partially frozen due to influence of low-temperature outside air. If the refrigerant is at least partially frozen, its cooling function is deteriorated, heat generation of a semiconductor element cannot be suppressed, and there is a possibility that the semiconductor element becomes high temperature and is destroyed.

In order to cope with this problem, it is thought that a heater is attached to a heat pipe, and a current is flowed to the heater in a temperature environment below the freezing point of the refrigerant to apply a heat amount to the heat pipe, thereby preventing freezing of the refrigerant. Alternatively, when the refrigerant freezes and the cooling performance is not sufficiently exhibited and the semiconductor element becomes high temperature and the output of the power conversion device becomes large, it is also considered to provide a high-temperature protection function such as controlling the output of the power conversion device to be lowered or taking measures such as stoppage of operation on the semiconductor element side.

### CITATION LIST

### Patent Literature

[1] JP 1106-276742 A

### SUMMARY

### Technical Problem

However, when the ambient temperature becomes equal to or lower than a predetermined temperature, it is undesirable to operate the heater to prevent freezing of the refrigerant because the heater consumes a large amount of power. Further, the cost of the heater increases the cost of the cooling device, and the cooling device is also increased in size because of the installation of the heater.

Further, in the power conversion device which is an application example of the cooling device, it is required to operate for 24 hours while its output is stabilized. Therefore, when the refrigerant freezes, it is not desirable to perform control for lowering the output of the power conversion device or to take measures for stopping the operation.

An object of the present invention is to provide a cooling device capable of preventing the refrigerant from freezing in a low temperature environment and stably cooling a cooling object.

### Solution to Problem

According to one aspect of the present invention, a cooling device includes a heat pipe connected to a cooling object, air cooling means for cooling a heat radiating portion of the heat pipe, a temperature sensor for measuring a temperature around a device, and control means for controlling the air cooling means. The control means operates the air cooling means in a first mode if the temperature measured by the temperature sensor is higher than a reference temperature, and operates the air cooling means in a second mode if the temperature measured by the temperature sensor is not higher than the reference temperature, wherein cooling capacity of the second mode is lower than that of the first mode.

### BRIEF DESCRIPTION OF DRAWINGS

FIG. 1 is a schematic diagram showing an example of a power conversion device including a cooling device according to an embodiment.

FIG. 2 is a diagram showing an example of a heat exchanger included in the cooling device of the embodiment.

FIG. 3 shows an example of the operation of the heat exchanger.

FIG. 4 is a flow chart showing an example of operation of the cooling device.

FIG. 5 is a diagram showing an example of the relationship between an ambient temperature and an element temperature and operations of the fan 22 and the louver 24.

### DESCRIPTION OF EMBODIMENTS

Hereinafter, embodiments according to the present invention will be described with reference to the drawings. In the description of each embodiment, terms representing directions (e.g., up, down, left, right, etc.) are used as necessary, however, the present invention is not limited by these terms. In each drawing, substantially the same functions and elements are denoted by the same reference numerals, and description thereof is omitted as necessary. Representation of each element is illustrative only and does not deny that each element is represented in other representations. Further, the drawings are schematic, and relationship between thickness and a planar dimension, ratio of the thickness of each layer, and the like may be different from actual ones. In addition, the drawings may include portions having different dimensional relationships and ratios from each other.

Embodiments which will now be described include a cooling device which is applied to a power conversion device and suppresses heat generation of a semiconductor element performing on/off switching for power conversion. However, a cooling object to be cooled by the cooling device is not limited to a semiconductor element, and any heat source may be cooled. Further, an application product of the cooling device is not limited to the power conversion device, and there are various products such as general electronic equipment. When the cooling device is applied to a power conversion device, it can be applied to any type of power conversion device.

### [Power Conversion Device]

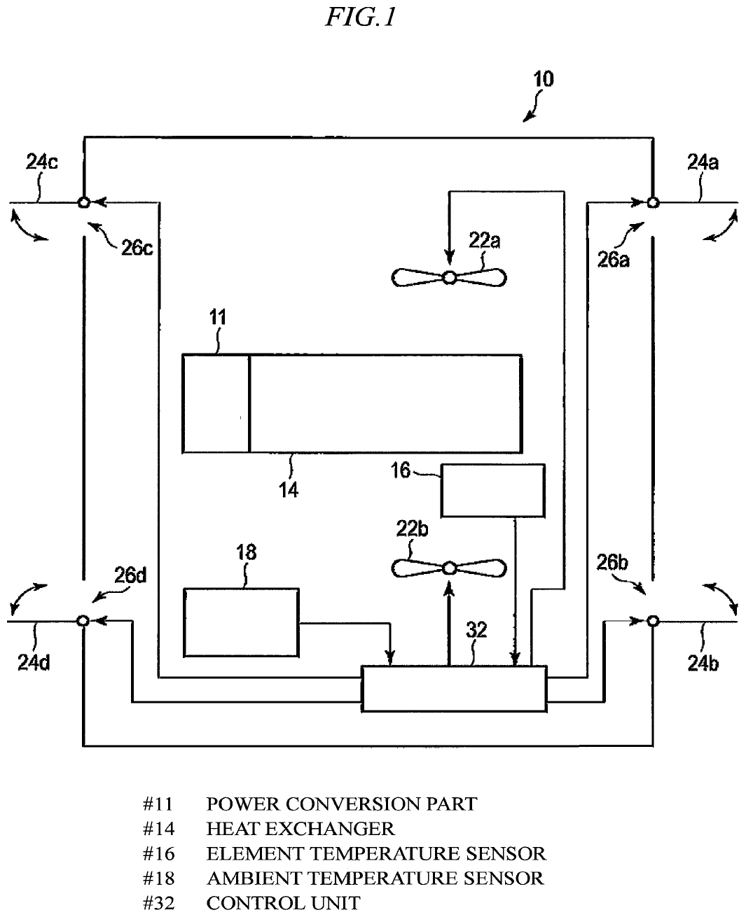

Referring to FIG. 1, an example of a schematic structure of a power conversion device including an embodiment of a cooling device will be described.

The power conversion device is housed in, for example, a rectangular parallelepiped housing 10. The housing 10 accommodates, for example, a power conversion part 11, a heat exchanger 14, an element temperature sensor 16, fans 22a and 22b, and the like. The reference numerals 22a and 22b are used to specify one fan, but the reference numeral 22 is used to indicate an arbitrary fan and to generically refer to the fan.

When the power conversion device is applied to, for example, a photovoltaic power generation system, DC power output from a photovoltaic cell is supplied to the power conversion part 11 and converted into AC power. Since a known inverter can be used as the power conversion part 11, a detailed description thereof is omitted. In the case of a photovoltaic system, the power conversion device may be installed outdoors.

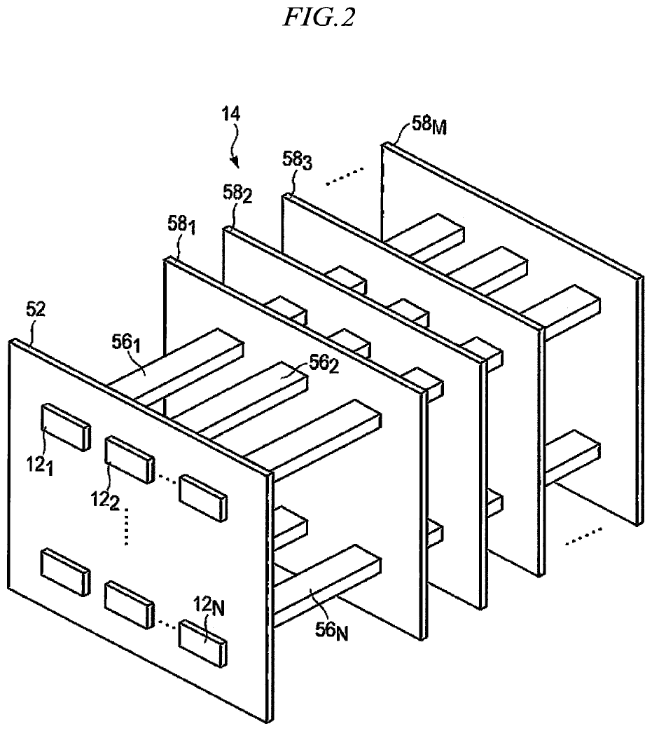

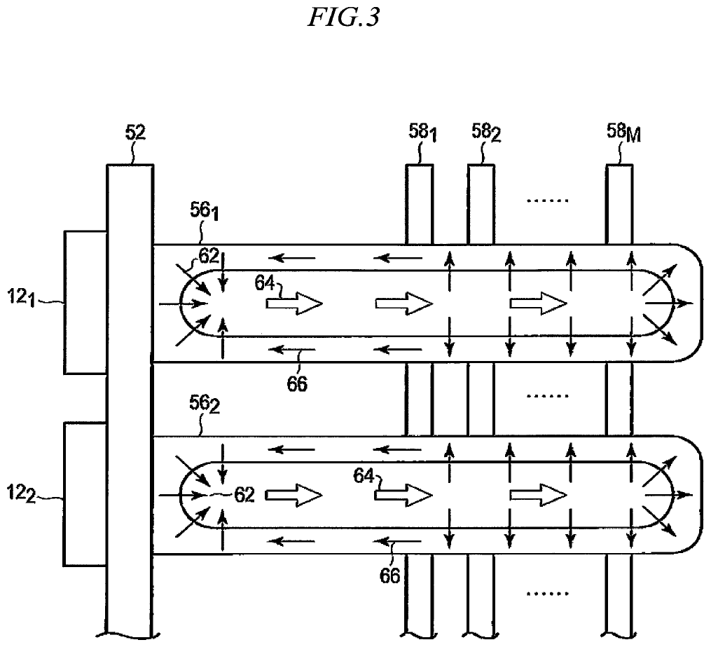

The heat exchanger 14 is a heat pipe type heat exchanger, and is disposed in a horizontal direction in a substantially central portion of an internal space of the housing 10. The details of the heat exchanger 14 will be described later with reference to FIGS. 2 and 3. One end of a heat pipe included in the heat exchanger 14 is a heat receiving portion, and another end is a heat radiating portion.

The fans 22a and 22b are provided above and below the heat radiating portion side of the heat exchanger 14. The fan 22 constitutes an air cooling system which forces air to convect in one direction, e.g. from bottom to top. A blower may be used instead of the fan 22. A revolution speed of the fan 22 or the blower is variable so that the blowing intensity can be changed. Positions of the air cooling system is not limited to the upper and lower sides of the heat exchanger 14, and may be left and right sides. The number of fans 22 is not limited to two, and two or more multiple fans may be provided.

Air ports 26a, 26b, 26c, and 26d are provided at a top portion and a bottom portion of the left and right side surfaces of the housing 10. The reference numerals 26a, 26b, 26c, and 26d are used to specify one air port, but the reference numeral 26 is used to indicate an arbitrary air port and to generically refer to the air ports. The air port 26 may be formed over the entire side surface, or may be formed from a large number of small air ports. The shape of the air port is not limited to a long-and-narrow rectangular shape, and any shape is possible. Further, the air port may not be a complete opening, but may be a mesh shape. Further, the air ports 26 may be provided on all of the front, rear, left, and right side surfaces of the housing 10.

The air ports 26a and 26b are provided on the side surface of the heat radiating portion side, and the air ports 26c and 26d are provided on the side surface of the heat receiving portion side. The fan 22a operates as an exhaust fan, and the fan 22b operates as an intake fan. Therefore, the air port 26a in the vicinity of the exhaust fan 22a acts as an exhaust port, and the air port 26b in the vicinity of the intake fan 22b acts as an intake port. Although the fan 22 is not provided in the vicinity of the air ports 26c and 26d on the heat receiving portion side, since high-temperature air heated on the heat receiving portion side rises, the air port 26c acts as an exhaust port and the air port 26d acts as an intake port, and natural convection from the bottom to the top also occurs on the heat receiving portion side in the housing 10. Cooling by natural convection using the air ports 26c and 26d is also referred to as a self-cooling system. Since the air port 26 is preferably in the vicinity of the fan 22, an installation location of the air port 26 is determined according to an installation location of the fan 22.

The air ports 26a, 26b, 26c, and 26d are provided with louvers 24a, 24b, 24c, and 24d as shutter members that are driven to open the air ports 26 normally but close the air ports 26 at predetermined timing. As the shutter member, a damper may be used. The symbols 24a, 24b, 24c, 24d are used to specify one louver, but the symbol 24 is used to indicate an arbitrary louver and to generically refer to the louvers. An example of the louver 24 is a blade whose one end is pivotally supported by the housing 10, and the air port 26 is opened and closed by swinging thereof. The louver 24 may be a product of any shape and may be composed of a plurality of blades, or a sliding blade may be used instead of a swinging blade.

Although not shown, a partition wall is provided in a vertical direction at a substantially central portion of the internal space of the housing 10, and the housing 10 is separated into a heat receiving portion side and a heat radiating portion side. The outside air may include moisture, sand, dust, and the like that affect the power conversion part 11, and the partition wall has a function of preventing the air that enters the housing 10 through the intake port 26b from directly hitting the power conversion part 11.

An ambient temperature sensor 18 capable of measuring an ambient temperature outside the device is provided in the vicinity of one air port, for example, an air port 26d, on the heat receiving portion side in the housing 10. Although the actual ambient temperature outside the device and the temperature measured in the vicinity of the air port 26d are different from each other, the extent of difference can be known in advance. Therefore, the actual ambient temperature can be calculated based on the measured value of the ambient temperature sensor 18. It should be noted that, although the ambient temperature can be measured more accurately if the ambient temperature sensor 18 is provided outside the housing 10, the sensor may be provided inside the housing 10 if the power conversion device is installed outdoors because the sensor may fail under a severe environment.

The element temperature sensor 16 is disposed in the passage of the cooling air blown from the intake fan 22b. The element temperature sensor 16 obtains an element temperature of a semiconductor element constituting the power conversion part 11, for example, a diode, a thyristor, a gate turn-off thyristor (GTO), or an insulated gate bipolar transistor (IGBT). Temperature of the cooling air relates to the element temperature, and it can be known in advance how much the difference exists between an actual element temperature of the semiconductor element and the temperature of the cooling air. Therefore, the element temperature sensor 16 can calculate the actual element temperature based on the measured value of the cooling temperature. Since the cooling air can also be measured in the heat radiating portion of the heat exchanger 14 (actually, heat radiating fins 58 shown in FIG. 2), the element temperature sensor 16 may be installed in the heat radiating portion of the heat exchanger 14. It should be noted that, although the element temperature can be measured more accurately if the element temperature sensor 16 is provided in the vicinity of the semiconductor element of the power conversion part 11, the element temperature sensor 16 may be provided in the passage of the cooling air because the vicinity of the element may become a high temperature and the sensor may fail.

Outputs of the element temperature sensor 16 and the ambient temperature sensor 18 are supplied to a control unit 32. The control unit 32 includes a CPU and the like, and controls the fan 22 and the louver 24 in accordance with the temperature measured by the sensors 16 and 18 to control the cooling operation. The control unit 32 may be configured by hardware. The control unit 32 does not have to be provided inside the housing 10, and may be provided outside the housing 10, for example, in a monitoring room or the like of the power conversion device.

### [Heat Pipe Type Heat Exchanger]

FIG. 2 shows an example of the configuration of a heat pipe type heat exchanger. A large number of semiconductor elements included in the power conversion part 11, for example, semiconductor chips 12₁ to 12_{N} on which an IGBT is formed, are disposed on the surfaces of a heat receiving plate 52. N is any positive integer equal to or greater than 2. A plane of the heat receiving plate 52 is substantially along a vertical direction. One end of each of the plurality of heat pipes 56₁ to 56_{N} is connected to a rear surface of the heat receiving plate 52 at a position corresponding to the semiconductor chips 12₁ to 12_{N}. As a result, one end of each of the heat pipes 56₁ to 56_{N} serves as a heat receiving portion. A plurality of heat radiating fins 58₁ to 58_{M} are provided on the other end side of the heat pipes 56₁ to 56_{N}. M is any positive integer equal to or greater than 2. Each of the heat radiating fins 58₁ to 58ₘ crosses all of the heat pipes 56₁ to 56_{N}. The heat pipes 56₁ to 56_{N} may be horizontally provided so as to be orthogonal to the heat receiving plate 52 and the heat radiating fins 58₁ to 58_{M}, or may be slightly obliquely provided so that the heat receiving plate 52 side is high and the heat radiating fin 58_{M} side is low. The heat radiating fins 58₁ to 58_{M} are located in the path of the cooling air convected by the fans 22a and 22b. Reference numerals 12₁ to 12_{N}; 56₁ to 56_{N}; 58₁ to 58_{N} are used when specifying one of the semiconductor elements, heat pipes, and heat dissipation fins, but reference numerals 12; 56; 58 are used when referring to any semiconductor element, heat pipe, and heat dissipation fin, and when generically referring thereto.

### [Heat Pipe]

FIG. 3 shows an example of a cross section of the heat pipe 56. The heat pipe 56 is a metal pipe having a vacuum inside, and is filled with a refrigerant (also referred to as a working liquid). When one end (heat receiving portion) of the heat pipe 56 receives heat 62 from the semiconductor chip 12 via the heat receiving plate 52, the refrigerant undergoes a phase change to steam, receives latent heat, and the steam pressure in the heat receiving portion rises. Since the heat radiating fins 58 at the other end (the heat radiating portion) of the heat pipe 56 are cooled by the fan 22 of the air cooling system, a steam pressure of the heat receiving portion is higher than a steam pressure of the heat radiating portion. Due to this pressure difference, the steam 64 receiving the latent heat moves to the heat radiating portion of the heat pipe 56. The steam 64 is condensed in a region where the heat radiating fins 58 are provided, and the latent heat received is released and propagated to the heat radiating fins 58, whereby the temperature of the heat radiating fins 58 rises. Since the temperatures of the heat radiating fins 58 are different from a temperature of air between the heat release fins 58, this causes the heat of the heat radiating fins 58 to propagate to the air between the heat radiating fins 58, and the temperature of the air between the heat radiating fins 58 rises. When cooled in the heat radiating portion, the steam 64 undergoes a phase change to a liquid by condensation and liquefies again. The liquefied refrigerant 66 is circulated to the heat receiving portion of the heat pipe 56 and vaporized again. In order to circulate the liquefied refrigerant 66 to the heat receiving portion, a wire mesh (wick) or a fine groove (groove) is provided on the inner wall of the heat pipe 56, and the refrigerant 66 is circulated to the heat receiving portion by the capillary action by the surface tension.

The heat pipe described above is known as a wick type heat pipe, but is not limited thereto, and a thermosiphon type heat pipe may be used. In the thermosiphon type, the heat pipe is installed vertically, and the heat receiving portion is set to the lower side, whereby the refrigerant vaporized in the heat radiating portion is naturally returned to the heat receiving portion by gravity. The installation direction of the wick type heat pipe is not limited to the horizontal direction, and may be installed in the vertical direction.

### [Operation of Cooling Device]

As described above, the heat generated in the semiconductor chip 12 is transmitted through the heat pipe 56 of the heat exchanger 14 and radiated from the heat radiating fins 58, thereby suppressing heat generation of the semiconductor chip 12. There are conditions under which the heat pipe 56 operates normally. That is, the refrigerant circulates in the heat pipe 56. If the power conversion device is installed in a cryogenic region below the freezing point, the heat exchanger 14 may be excessively cooled by the air cooling system (fan 22) using low-temperature outside air, and the refrigerant in the heat pipe 56 may be partially frozen. When the refrigerant freezes, the refrigerant cannot circulate in the heat pipe 56, and the heat exchange by the heat pipe 56 is hindered, so that the heat generation of the semiconductor chip 12 cannot be suppressed, and there is a possibility that the semiconductor chip 12 becomes high temperature and is destroyed. In this embodiment, freezing of the refrigerant is prevented by adjusting the cooling capacity of the air cooling system (fan 22) in accordance with the ambient temperature of the power conversion device.

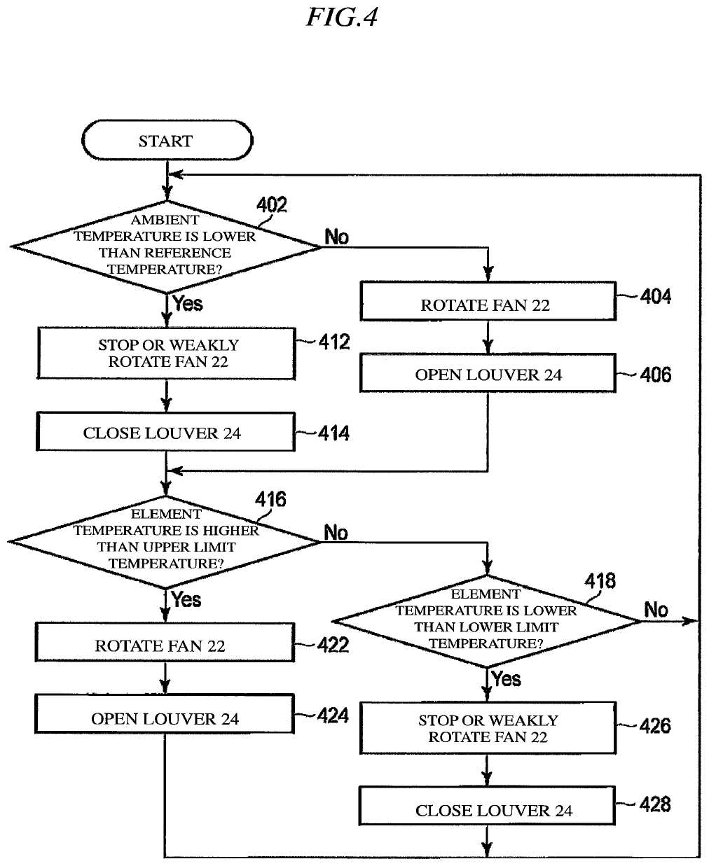

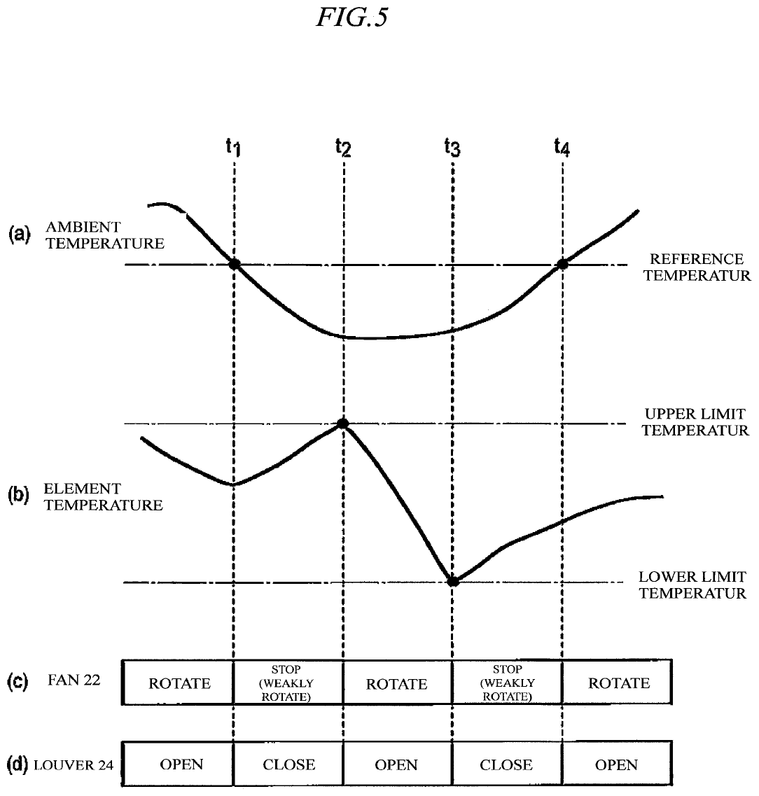

Cooling operation of the embodiment will be described with reference to FIGS. 4 and 5. FIG. 4 is a flowchart of the control unit 32, and FIG. 5 shows the relationship between the detected temperature of the temperature sensors 16 and 18 and operations of the fan 22 and the louver 24.

The control unit 32 examines the output of the ambient temperature sensor 18 to determine whether or not the ambient temperature is lower than a reference temperature (block 402). The reference temperature is a temperature at which the refrigerant starts to freeze, for example, a temperature in the vicinity of the freezing point. If the ambient temperature is not lower than the reference temperature, the control unit 32 causes the air cooling system to operate at normal cooling capacity. That is, the control unit 32 rotates the fan 22 at a normal intensity (rotation speed) (block 404), opens the louver 24, and opens the air port 26 (block 406).

The state up to this point is the state up to a time t₁ in FIG. 5. Since the fan 22 rotates at a normal intensity, outside air is taken into the housing 10 through the intake port 26b and is forced to convect from the bottom to the top of the heat exchanger 14 by the fan 22b, and the air is exhausted from the exhaust port 26a to the outside of the housing 10 by the fan 22a. As a result, the heat radiating portion (the heat radiating fin 58) of the heat exchanger 14 is cooled by the air cooling system, and heat generation of the semiconductor chip 12 is suppressed. On the other hand, on the side of the heat receiving portion, the outside air is taken into the housing 10 from the intake port 26d and is exhausted to the outside of the housing 10 from the exhaust port 26c, natural convection from the bottom to the top occurs, and the heat receiving side of the heat exchanger 14 is also cooled.

If the ambient temperature falls below the reference temperature, the control unit 32 stops the cooling function of the air cooling system or reduces the cooling capacity (or weakens the cooling function) because the refrigerant may freeze. That is, the control unit 32 stops the rotation of the fan 22 (the revolution speed is set at 0) or lowers the revolution speed (or weakly rotates) (block 412), closes the louver 24, closes the air port 26, and seals the housing 10 (block 414).

The state up to this point is the state from time t₁ (to time t₂) in FIG. 5. Since the fan 22 stops rotating or rotates slightly, the forced convection does not substantially occur in the housing 10, and the cooling of the heat exchanger 14 by the air cooling system is interrupted. Therefore, the element temperature rises and freezing of the refrigerant is prevented.

Further, since the air port 26 is closed by the louver 24, outside air is not taken into the housing 10, and condensation is also prevented. It should be noted that, if the purpose is not to prevent condensation, the closing operation of the louvers 24 of the block 414 is not necessarily required. When the ambient temperature is lower than the reference temperature, at least the cooling operation by forced convection by the fan 22 may be stopped, and cooling by natural convection may be continued. Alternatively, the reference temperature may be set in two stages, and the forced convection of the fan 22 may be stopped when the ambient temperature becomes lower than a higher reference temperature, and the louver 24 may be closed and the natural convection may also be stopped when the ambient temperature becomes lower than a lower reference temperature.

As the cooling operation stops, the element temperature rises. Two limit temperatures are defined for the element temperature. A limit temperature on high temperature side (an upper limit temperature) is a limit (allowable limit) at which the semiconductor element operates safely, and is a temperature at which destruction of the semiconductor element may occur upon reaching and exceeding this temperature. The upper limit temperature varies depending on products, but is, for example, −7° C. or the like. When the refrigerant is pure water and low temperature countermeasures are taken, −15° C. may be used, and when low temperature countermeasures such as antifreeze are taken, about −25° C. may be used. A limit temperature on low temperature side (a lower limit temperature) is lower than a lower limit temperature of the cooling device. After the processing of block 406 or 414, the control unit 32 examines the output of the element temperature sensor 16 to determine whether or not the element temperature is higher than the upper limit temperature (block 416). When the element temperature is higher than the upper limit temperature, the control unit 32 operates the air cooling system with a normal cooling capacity because the semiconductor element may be destroyed if left as it is. That is, the control unit 32 rotates the fan 22 at a normal intensity (rotation speed) (block 422), opens the louver 24, and opens the air port 26 (block 424).

The state up to this point is the state from time t₂ (to time t₃) in FIG. 5. Since the fan 22 rotates at a normal intensity, outside air is taken into the housing 10 through the intake port 26b and is convected upward from the bottom of the heat exchanger 14 by the fan 22b, and the air is exhausted out of the housing 10 through the exhaust port 26a by the fan 22a. As a result, the heat radiating portion (the heat radiating fin 58) of the heat exchanger 14 is cooled by the air cooling system, and heat generation of the semiconductor chip 12 is suppressed. On the other hand, on the side of the heat receiving portion, the outside air is taken into the housing 10 from the intake port 26d and is exhausted to the outside of the housing 10 from the exhaust port 26c, natural convection from the bottom to the top occurs, and the heat receiving side of the heat exchanger 14 is also cooled.

After the execution of block 424, the processing of the control unit 32 returns to the determination of the ambient temperature in block 402.

If the element temperature is not higher than the upper limit temperature, the control unit 32 determines whether or not the element temperature is lower than the lower limit temperature (block 418). When the element temperature is not lower than the lower limit temperature, the process of the control unit 32 returns to the determination of the ambient temperature in block 402. The order of execution of the upper limit determination (block 416) and the lower limit determination (block 418) of the element temperature may be reversed.

When the element temperature is lower than the lower limit temperature, the control unit 32 stops the cooling function of the air cooling system or reduces the cooling capability (or weakens the cooling function) because there is a possibility that the refrigerant is frozen. That is, the control unit 32 stops the rotation of the fan 22 (the rotation speed is set to 0) or lowers the rotation speed (or weakly rotates) (block 426), closes the louver 24, closes the air port 26, and seals the housing 10 (block 428).

The state up to this point is the state from time t₃ (to T₄) in FIG. 5. Since the fan 22 stops rotating or rotates slightly, the forced convection does not substantially occur in the housing 10, and the cooling of the heat exchanger 14 by the air cooling system is interrupted. Therefore, the element temperature rises and freezing of the refrigerant is prevented.

Further, since the air port 26 is closed by the louver 24, outside air is not taken into the housing 10, and condensation is also prevented. Similar to block 414, the closing operation of louver 24 in block 428 is not necessary if it is not intended to prevent condensation. When the ambient temperature is lower than the reference temperature, at least the cooling operation by forced convection by the fan 22 may be stopped, and cooling by natural convection may be continued. Alternatively, the reference temperature may be set in two stages, and the forced convection of the fan 22 may be stopped when the ambient temperature becomes lower than a higher reference temperature, and the louver 24 may be closed and the natural convection may also be stopped when the ambient temperature becomes lower than a lower reference temperature.

After the execution of block 428, the processing of the control unit 32 returns to the determination of the ambient temperature in block 402. If the ambient temperature is higher than the reference temperature (NO in block 402), the control unit 32 causes the air cooling system to operate at normal cooling capacity. That is, the control unit 32 rotates the fan 22 at a normal intensity (rotation speed) (block 404), opens the louver 24, and opens the air port 26 (block 406). The state up to this point is the state after time is in FIG. 5.

### SUMMARY OF EMBODIMENTS

In a cooling device for cooling a semiconductor element of a power conversion device using a heat pipe type heat exchanger, the heat pipe is cooled by an air cooling system. When the outside air is at a low temperature such as below freezing point, if the air cooling system is operated as usual, the heat pipe is excessively cooled, the refrigerant is partially frozen, and there is a possibility that the heat generation of the semiconductor element cannot be suppressed. According to the embodiment, an ambient temperature (an outside air temperature) is measured and the mode of operation of the air cooling system is changed when the ambient temperature drops to a reference temperature. For example, the operation is stopped or the cooling capacity is lowered. As a result, freezing of the refrigerant in the heat pipe can be prevented. Furthermore, the element temperature is also measured, and even when the ambient temperature is lower than the reference temperature, the cooling operation of the air cooling system is resumed when the element temperature rises to an allowable temperature. As a result, high temperature destruction of the element can be prevented. Further, when the element temperature is lowered to the lower limit temperature by the cooling operation of the air cooling system in a case where the ambient temperature is lower than the reference temperature, the operation mode of the air cooling system is changed. For example, the operation is stopped or the cooling capacity is lowered. As a result, freezing of the refrigerant in the heat pipe can be prevented. When the ambient temperature is equal to or lower than the reference temperature, the operation of the air cooling system is stopped or adjusted to the normal operation and the like in accordance with the element temperature, whereby the high temperature destruction of the element and the freezing of the refrigerant in the heat pipe can be prevented. Further, when the ambient temperature drops to the reference temperature, the louvers are closed, the air ports are closed, and the housing is sealed, so that condensation due to the low-temperature outside air is prevented from occurring in the power conversion unit.

The heater for applying the amount of heat to the heat pipe, which is conventionally required, becomes unnecessary, so that power is not consumed by the heater, and the cost of the cooling device is not increased due to the cost of the heater, or the cooling device is not increased in size due to the installation of the heater.

When the cooling device is applied to a power conversion device, the power conversion device can stably operate for 24 hours. In the power conversion device, heat generation loss increases as the capacity of the semiconductor element increases and the speed increases, but according to the embodiment, the cooling efficiency of the semiconductor element can be improved and the device can be miniaturized.

### Modification

As the shutter member for closing the air port 26, the louver 24 driven by the control unit 32 based on the output of the temperature sensors 16 and 18 is used, but a bimetallic louver may be used to open and close the air port in accordance with the ambient temperature detected by a bimetal. In this case, while the fan 22 is stopped or slightly rotated, the louvers 24 may be driven to open and close in accordance with the detection result of the element temperature sensor 16, as at times t2 and t3 in FIG. 5.

Although both the ambient temperature and the element temperature are measured, since the lower limit temperature of the element temperature is related to a reference value of the ambient temperature, only the element temperature may be measured, and the ambient temperature may not be measured. In this case, blocks 402, 404, 406, 412, and 414 of the flowchart of FIG. 4 are omitted. The rotation of the fan 22 and the opening and closing of the louvers 24 are controlled based only on the element temperature.

It is to be noted that the present invention is not limited to the foregoing embodiments, and constituent elements can be modified and changed into shapes without departing from the scope of the invention at an embodying stage. For example, although a cooling device used for cooling a semiconductor element of a power conversion device installed outdoors has been described, the cooling device can be applied to a power conversion device installed indoors, and can also be applied to a device for cooling a heat source of a general electronic device other than the power conversion device. In addition, various inventions can be formed by appropriately combining a plurality of constituent elements disclosed in the above embodiments. For example, several constituent elements may be eliminated from all constituent elements disclosed in the embodiments. Furthermore, the constituent elements of different embodiments may be combined as appropriate.

### REFERENCE SIGNS LIST

14 . . . Heat exchanger
16 . . . Element temperature sensor
18 . . . Ambient temperature sensor
22a, 22b . . . Fan
24a, 24b, 24c, 24d . . . Louver
26a, 26b, 26c, 26d . . . Air port
32 . . . Control unit

1. A cooling device comprising:
a heat exchanger connected to a cooling object;
air cooling means for cooling the heat exchanger;
a first temperature sensor for measuring a device-around temperature;
control means for operating the air cooling means in a first mode when a temperature measured by the first temperature sensor is higher than a first reference temperature, and operating the air cooling means in a second mode when the temperature measured by the first temperature sensor is not higher than the first reference temperature, the second mode having a cooling capacity lower than that of the first mode;
a housing accommodating the heat exchanger and the air cooling means, and including an air port;
a shutter member provided in the housing and opening or closing the air port; and
driving means for driving the shutter member to open the air port when the temperature measured by the first temperature sensor is higher than a second reference temperature set lower than the first reference temperature, and driving the shutter member to close the air port when the temperature measured by the first temperature sensor is not higher than the second reference temperature.

2. The cooling device according to claim 1, further comprising a second temperature sensor for measuring a temperature of the cooling object,
wherein the control means operates the air cooling means in the first mode when the temperature measured by the second temperature sensor rises to a first temperature, and operates the air cooling means in the second mode when the temperature measured by the second temperature sensor falls to a second temperature lower than the first temperature.

3. (canceled)

4. The cooling device according to claim 1, wherein
the control means stops operation of the air cooling means when the temperature measured by the first temperature sensor is not higher than the reference temperature.

5. A cooling method for a heat exchanger that receives heat from a cooling object and transfers the heat to a heat radiating portion,
wherein the cooling method cools the heat radiating portion by an air cooling system when an ambient temperature is higher than a first reference temperature,
wherein the cooling method stops cooling of the heat radiating portion by the air cooling system, or weakly cools the heat radiating portion by the air cooling system, when the ambient temperature is not higher than the first reference temperature,
wherein a housing accommodating the heat exchanger and the air cooling means is provided, and the housing includes an air port;
wherein a shutter member is provided in the housing, and the shutter member opens or closes the air port;
wherein the cooling method drives the shutter member to open the air port when the ambient temperature is higher than a second reference temperature set lower than the first reference temperature, and
wherein the cooling method drives the shutter member to close the air port when the ambient temperature is not higher than the second reference temperature.
